(19) United States
(12) Patent Application Publication
(10) Pub. No.: US 2015/0227425 A1
(43) Pub. Date: Aug. 13, 2015

(54) METHOD FOR ENCODING, DATA-RESTRUCTURING AND REPAIRING PROJECTIVE SELF-REPAIRING CODES

(71) Applicants: PEKING UNIVERSITY SHENZHEN GRADUATE SCHOOL, Shenzhen (CN); SHENZHEN BOYUAN TRAFFIC FACILITIES CO., LTD., Shenzhen (CN); SHENZHEN LONGGANG YWSOFT TECHNOLOGY CO., LTD., Shenzhen (CN)

(72) Inventors: Hui LI, Shenzhen (CN); Hanxu HOU, Shenzhen (CN); Shunhong YE, Shenzhen (CN); Wen NIE, Shenzhen (CN); Xuelei TAN, Shenzhen (CN)

(21) Appl. No.: 14/691,569

(22) Filed: Apr. 20, 2015

Related U.S. Application Data
(63) Continuation-in-part of application No. PCT/CN2012/083174, filed on Oct. 19, 2012.

(51) Int. Cl. G06F 11/10; H03M 13/00; H04L 29/08

(52) U.S. Cl. CPC G06F 11/1076; H04L 67/1097; H03M 13/616

(57) ABSTRACT

A method for encoding, data-restructuring and repairing projective self-repairing codes is provided. The method comprises the following steps: equally dividing original data; setting base finite fields which have an inclusion relation according to parameters of the equally divided data: a first finite field and a second finite field; partitioning a space constructed of B/C-dimensional vectors with its subgroup coset and choosing B/C subspaces among the subspaces, each chosen subspace corresponding to a storage node; arraying vectors of the B/C subspaces to obtain an encoding matrix; and according to each storage node's encoding vectors, obtaining encoding data stored therein, and storing the encoding data into the storage node.

### CROSS-REFERENCE TO RELATED APPLICATIONS

This application is a continuation-in-part of International Patent Application No. PCT/CN2012/083174 with an international filing date of Oct. 19, 2012, designating the United States, now pending, the contents of which, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, Mass. 02142.

### BACKGROUND OF THE INVENTION

1. Field of the Invention

The invention relates to distributed network storage, in particularly to encoding, data-restructuring and repairing of projective self-repairing codes.

2. Description of the Related Art

Network storage systems have garnered special attention in the recent past. Storage system may be of different types, such as, special infrastructure system which is built on P2P distributed memory system, data center, and storage area network. In a distributed memory system, there is usually storage node failure or document transmission loss; hence the network storage system must have redundancy. Redundancy can be realized through simple replicated data, although its storage efficiency is not high.

Erasure codes can provide an effective storage scheme which is different from the previous reproduction. A (n, k) MDS (Maximum Distance Separable) erasure code needs to divide an original file into “k” equal modules and generate “n” unrelated encoding modules through linear encoding. “n” nodes will store different modules and meet MDS attributes (any “k” modules among the “n” encoding modules can restructure the original file). Such encoding technique plays an important role in providing effective network storage redundancy, and it is particularly suitable for storage of large files and data backup of records.

However, owing to node failure or document loss, the system's redundancy may gradually disappear over time; hence, a solution is desired to ensure system redundancy. The EC (erasure codes) mentioned in the literature [R. Rodrigues and B. Liskov, “High Availability in DHTs: Erasure Coding vs. Replication”, Workshop on Peer-to-Peer Systems (IPTPS) 2005.] is effective in storage overhead; however, the communication overhead required for redundancy recovery is also very large. Prior art FIG. 1 illustrates that, as long as the number of valid nodes d≧k in the system, the original file can be obtained from the existing nodes. Prior art FIG. 2 illustrates the process in which information stored in failure nodes is recovered. Referring to the prior art figures, the process of recovery includes downloading data from k storage nodes in the system to restructure the original file; then the original file recode new modules and store them in new nodes. This recovery process shows that the network load required for repairing any one failure node is at least the contents stored in k nodes.

Prior art FIG. 3 describes the reproduction process after the failure of one node. The “n” storage nodes in the distributed system store “α” data respectively. After the failure of one node, new nodes can reproduce through downloading data from other d≧k live nodes. The download volume of each node is “β”. Each storage node “i” can be represented by a pair of nodes Vᵢₙⁱ, Vₒᵤₜⁱ. The pair of nodes are connected through an edge of which the volume is the memory capacity of this node (namely α). The reproduction process is described by an information flow chart. Xᵢₙ collects β data respectively from any d useable nodes in the system, and stores α data in Xₒᵤₜ through

$${X}_{i n} {}^{α} {X}_{out} .$$

All receivers can access Xₒᵤₜ. The maximum information flow from the information source to the information destination is determined by the minimum cutset in the figure; when the information destination needs to restructure the original file, the size of this flow cannot be smaller than the size of the original file.

In view of the foregoing discussion, a solution is desired for encoding, data-restructuring and repairing projective self-repairing codes which has fewer storage nodes for storing data and smaller bandwidth for data repairing.

### SUMMARY OF THE INVENTION

The technical proposal adopted in the invention to solve the technical problem is to structure an encoding method for the projective self-repairing codes used in the distributed storage system, including the following steps:

A) Dividing the original data with a size of B=2^{p} equally to C parts, with the size of each part being B/C; wherein, P is the positive integer, C=2^{C}, c is the positive integer smaller than p; each data can be represented as Bᵢ, i=1, 2, . . . , C; after the equal division.

B) Setting the base finite field F₂ and the second finite field F₂_{^{B/C}} according to the size of original data B and the number of equal division C; the space constituted by the B/C-dimensional vectors of the second finite field F₂_{^{B/C}} is the projective space P, and the dimensional subspace of space P forms the t-stretch set S, wherein, t+1|B/C and (2^{t+1}−1)|(2^{B/C}−1); the first finite field F₂_{^{t+1}} can be obtained from the t-stretch; wherein, F₂⊂ F₂_{^{t+1}} ⊂F_{q}_{^{B/C}}.

C) Dividing the space constituted by B/C-dimensional vectors in the second finite field F₂_{^{B/C}} into

$$\frac{{2}^{B / C} - 1}{{2}^{t + 1} - 1}$$

subspaces using its subgroup coset. B/C subspaces are chosen from the

$$\frac{{2}^{B / C} - 1}{{2}^{t + 1} - 1}$$

subspaces, with each selected subspace corresponding to one storage node, thus B/C storage nodes can be obtained.

D) Representing each subspace using the mutually independent t+1 vectors in the base finite field, and each storage node can store t+1 vectors of the base finite field; the data storage volume is α=Cα₁; wherein, α₁=t+1, C is the number of equal division; the t+1 vectors of one subspace are one row vector of the encoding matrix; vectors in the B/C subspaces arrange to make the encoding matrix; the data set obtained from one row of vector of the encoding matrix multiplied by the equally divided data blocks respectively is the data set stored in one storage node.

E) Obtaining the encoding data stored in each storage node according to the encoding vectors of each storage node and storing the encoding data in the storage node. More specifically, the multiplicative group of the second finite field F₂_{^{B/C}} in the step C) is F*₂_{^{B/C}}; w is the generating element of the multiplicative group F*₂_{^{B/C}} of the second finite field; F*_{q}_{^{t+1}} is the multiplicative group of the first finite field, and it is the subgroup of cyclic group F*₂_{^{B/C}}; its generating element is v; w^{a}F*_{q}_{^{t+1}}; wherein, a=0,

$$1 , … , \frac{{2}^{B / C} - 1}{{2}^{t + 1} - 1} - 1 ,$$

w is the generating element of the multiplicative group F*₂_{^{B/C}} of the second finite field, and the coset is the coset of subgroup F*₂_{^{t+1}}.

Moreover, the step C) further includes:

C1) Obtaining the multiplicative group F*₂_{^{B/C}} of the second finite field; suppose w is the generating element of the multiplicative group F*₂_{^{B/C}} of the second finite field; obtain the multiplicative group F*₂_{^{t+1}} of the first finite field; suppose v is the generating element of the multiplicative group F*₂_{^{t+1}} of the first finite field; for any w^{a}εF*₂_{^{B/C}}, w^{a}F*₂_{^{t+1}}={w^{a}·v^{j}|εF*₂_{^{t+1}}} is the coset of subgroup F*₂_{^{t+1}}; wherein, w^{a} is the representative element of the coset a=0,

$$1 , … , \frac{{2}^{B / C} - 1}{{2}^{t + 1} - 1} - 1 ; .$$

C2) Using the coset w^{a}F*₂_{^{t+1 divide the space of the second finite field F}}₂_{^{B/C}} to obtain

$$\frac{{2}^{B / C} - 1}{{2}^{t + 1} - 1}$$

subspace.

C3) Choosing B/C subspaces from the subspaces and make each subspace selected correspond to one storage node.

Further, the step D) further includes the following steps:

D1) Obtaining matrix gate T from the t+1 dimensional projective subspace. The matrix gate T is M×α₁ matrix gate, wherein M is the number of matrix row,

$$M = \frac{{2}^{B / C} - 1}{{2}^{t + 1} - 1} ;$$

α₁ is the queue of the matrix gate T, the elements in each row are the t+1 mutually independent elements in each coset w^{a}F*₂_{^{t+1}};

D2) Choosing the first B/C rows of the matrix gate T to obtain the encoding matrix T′; elements in one row of the encoding matrix T′ are the encoding vectors of one storage node.

More specifically, the step E) further includes:

Integrating the data stored in the k storage node one by one as {BᵢV_{(k-1)α}_{₁}^{T}, . . . , BᵢVₖₐ_{₁}^{T}} to obtain the encoding data stored respectively in different storage nodes; wherein, Bᵢ is the data block after the equal division, ν^{T} is the row vector of the encoding matrix corresponding to the storage node; the value range of k is k=1, 2, . . . , B/C.

The invention also relates to a method for restructuring data in the storage system which adopts the encoding method of the projective self-repairing codes, including the following steps:

I) Choosing C storage nodes arbitrarily in B/C storage nodes; wherein, C is the number of equal division during the encoding of the original data, and B is the size of the original file;

J) Downloading the data from the node selected and restructure the data according to its encoding vectors;

K) Determining whether the data reconstruction has been finished; if so, exit from the data reconstruction; otherwise, carry out the next step;

L) Choosing any one storage node from the unselected storage nodes, thus there will be one more selected storage node, and then return to step J).

More specifically, the step J) further includes obtaining the encoding vectors of the storage nodes selected from the server respectively, or obtaining the encoding vectors of the selected storage nodes from them.

The invention also relates to a method for repairing invalid storage nodes in the storage system which adopts the encoding method of the projective self-repairing codes, including the following steps:

M) Confirming a storage node has become invalid and obtain the encoding vectors of the storage node from the server.

N) Choosing any valid storage node and obtain its encoding vectors.

O) Obtaining the other storage node relating to the selected storage node, and obtain the encoding vectors of the invalid storage node through the encoding vectors of the selected storage node and the other storage node.

P) Downloading the data of the selected storage node and its relating storage node, and obtain the data of the invalid storage node according to these data and store the data in a new storage node to finish the data recovery.

More specifically, in the step O), the encoding vectors of the selected storage node plus the encoding vectors of the other storage node equals to the encoding vectors of the invalid storage node.

More specifically, in the step P), the data stored in the selected storage node and the relevant storage nodes are reconstructed to obtain the data stored in the invalid storage node.

Implementation of the encoding, data reconstruction and repairing method of projective self-repairing codes of the invention has the following beneficial effects: The second finite field obtained according to the data size of the original data and the number of data blocks divided is divided into several subspaces, and B/C subspaces are selected, with each selected subspace corresponding to a storage node; the encoding data of the storage node is determined, and the encoding data stored in each storage node all include each data block divided equally in the original file. When repairing the failure node, the data stored in the invalid storage node can be obtained by choosing any one storage node, finding the storage nodes that correspond to the selected storage node, and then downloading the data of these storage nodes and restructuring these data. Therefore, its calculation is simple and the overhead is less.

### BRIEF DESCRIPTION OF THE DRAWINGS

FIG. 1 is a schematic diagram showing a data restructuring process of EC in the prior art;

FIG. 2 is a schematic diagram showing a data repairing process of EC in the prior art;

FIG. 3 is a schematic diagram showing a repairing process after one node of RGC becomes invalid in the prior art;

FIG. 4 is a flowchart of an exemplary method for encoding, data-restructuring and repairing projective self-repairing codes, in accordance with an embodiment;

FIG. 5 is a schematic diagram for the encoding data stored in a storage node, in accordance with an embodiment;

FIG. 6 is a flow chart of an exemplary process for data-restructuring, in accordance with an embodiment;

FIG. 7 is a flow chart of an exemplary process for data repairing, in accordance with an embodiment;

FIG. 8 is a schematic diagram for performance evaluation when C equals to 2 and k equals to 4 in PPSRC, in accordance with an embodiment;

FIG. 9 is a schematic diagram for performance evaluation when C equals to 2 and k equals to 8 in the PPSRC, in accordance with an embodiment; and

FIG. 10 is a schematic diagram showing storage of storage nodes of PPSRC (8, 2), in accordance with an embodiment.

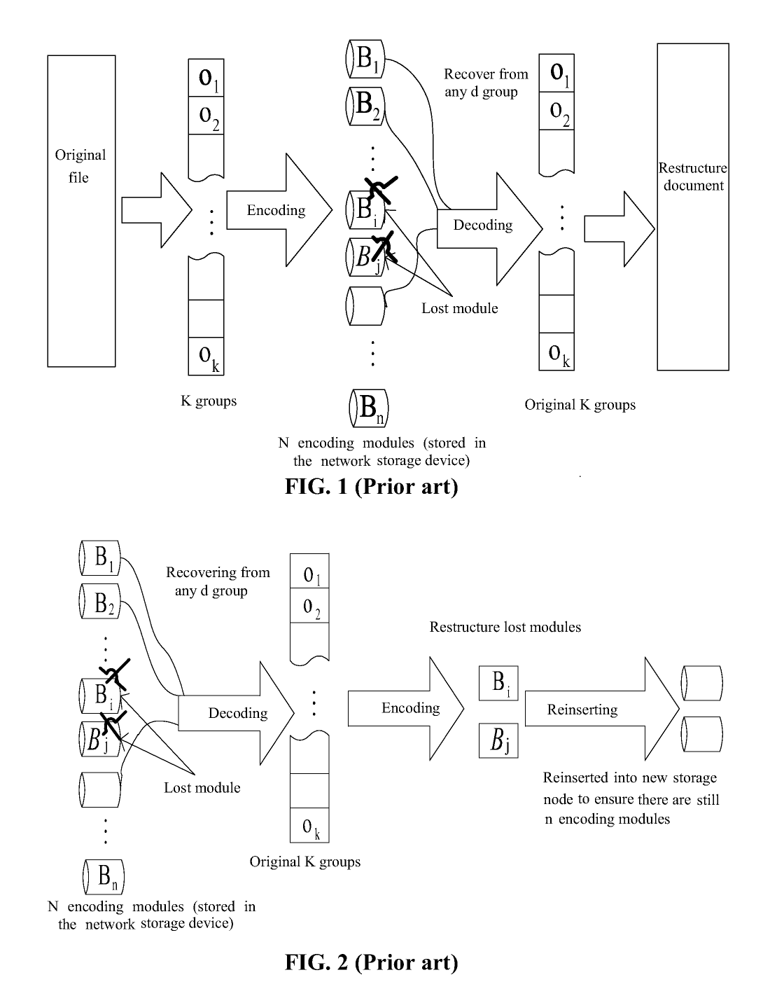

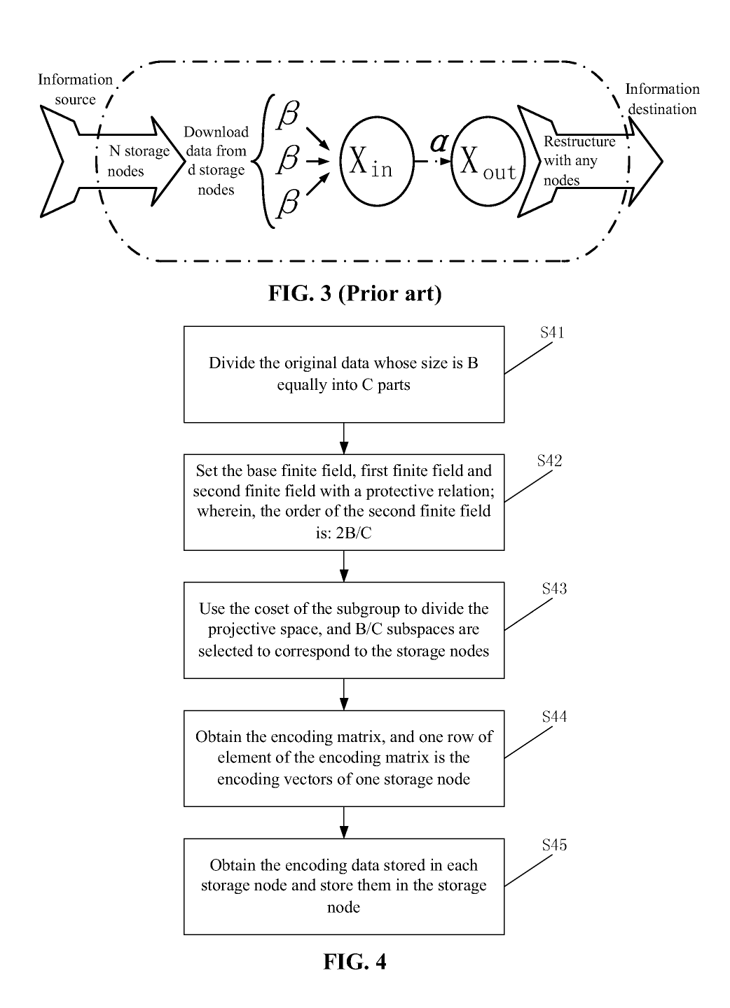

### DETAILED DESCRIPTION OF THE EMBODIMENTS

The following detailed description includes references to the accompanying drawings, which form part of the detailed description. The drawings show illustrations in accordance with example embodiments. These example embodiments are described in enough detail to enable those skilled in the art to practice the present subject matter. However, it will be apparent to one of ordinary skill in the art that the present invention may be practiced without these specific details. In other instances, well-known methods, procedures and components have not been described in detail so as not to unnecessarily obscure aspects of the embodiments. The embodiments can be combined, other embodiments can be utilized or structural and logical changes can be made without departing from the scope of the invention. The following detailed description is, therefore, not to be taken as a limiting sense.

In this document, the terms “a” or “an” are used, as is common in patent documents, to include one or more than one. In this document, the term “or” is used to refer to a nonexclusive “or,” such that “A or B” includes “A but not B,” “B but not A,” and “A and B,” unless otherwise indicated.

Referring to the figures, and more particularly to FIG. 4 a method for encoding, data-restructuring and repairing projective self-repairing codes is provided, in accordance with an embodiment. The encoding process includes, at step S41, original data whose size is B is equally divided into C parts. The original data, which may be as an example of size B=2^{p} is equally divided into C parts. The size of each divided part being B/C. P may be a positive integer, C=2^{c}, where c is a positive integer smaller than p; each data can be represented as Bᵢ, where i=1, 2, . . . , C; after the equal division.

The concept of projective space will be introduced at this point to enable easier understanding of subsequent portions of the description.

Considering the finite field of q order is F_{q}, and q is the power of prime integer p, the m dimensional vector in the finite field is represented as PG (m−1, q), and the vector is called a projective space. All vectors involved in this paper are row vectors.

Projective space is defined in such a way that, in the n-dimension affine space kⁿ in the field k, the set constituted by all straight lines passing through the origin is called the projective space of field k. Here, the field k can be a complex field, and so on. From the basic mathematics concept, one coordinate system corresponds to one affine space. Linear transformation is required when the vector changes from one coordinate system to the other coordinate system. For a point, the affine transformation is required.

Suppose P is the projective space, t-stretch of the projective space P is the t dimensional subspace of projective space P, and the set of t dimensional subspace is S, and the set divides the projective space P into several t dimensional subspaces, then, each point in the projective space P only belongs to one t dimensional subspace in the set S.

If P=PG (m−1, q) is a finite projective space, t-stretch can exist on condition that the number of points in t dimensional subspace can divide the number of points in the whole space exactly, namely,

$$\frac{{q}^{t + 1} - 1}{q - 1} \vert \frac{{q}^{m} - 1}{q - 1} ,$$

so (q^{t+1}−1)|(q−1), and the necessary and sufficient condition for this formula is (t+1)|m. If and only if (t+1)|m, t-stretch exists in the projective space P=PG(m−1, q).

The system construction of the stretch can be obtained through the expansion of the following finite field. Let's suppose (t+1)|m and consider the base finite field F0=F_{q}, the first finite field F₁=F_{q}_{^{t+1}} and the second finite field F₂=F_{q}_{^{m}}. The relation among the finite fields F0, F₁ and F₂ is F0⊂F₁⊂F₂. The second finite field F₂ is an m dimensional space V calculated in the base finite field F0, and the subspaces of space V can constitute projective space P=PG(m, q). Therefore, the first finite field F₁ is the (t+1) dimensional subspace of the space V, namely the t dimensional projective subspace of the projective space P. The coset in finite field is a special case of projective space. The coset of the second finite field F₂ and its subset F₁ is aF₁, aεF₂. The coset divides the multiplicative group in the second finite field F₂ into several parts. In this way, they constitute one t stretch of the space P.

In a distributed memory system, the size of the file is B and the file is stored in n storage nodes, with the size in each node being α. When a node becomes invalid, d nodes from the rest (n−1) nodes will be connected, and β data will be downloaded from d nodes respectively. PPSRC (n, k) is used to represent the practical self-repairing code; wherein, n is the number of storage nodes, and k is the number of nodes needed to be downloaded for reconstructing the original data.

In step S42, the base finite field, first finite field and second finite field with a protective relation are set, wherein the order of the second finite field is 2^{B/C}. In this step, the base finite field F0 is set as F₂, and the second finite field F₂ is set as F₂_{^{B/C}} according to the size of original data and the number of its equal division C. The space constituted by the B/C-dimensional vectors of the finite field F₂_{^{B/C}} is the projective space P, the t dimensional subspace of space P forms t-stretch set S, wherein t+1|B/C, and (2^{t+1}−1)|(2^{B/C}−1). The first finite field F₁ obtained using the t-stretch is F₂₊₁, wherein, F₂⊂F₂_{^{t+1}} ⊂F_{q}_{^{B/C}}. In other words, in the embodiment, considering the practicability of the restructured codes, the base finite field of the codes restructured is F₂. In this embodiment, for PPSRC, suppose the file size is B=2^{P}, p is a positive integer, unit block, and each block has L bits. Firstly, the original data is divided into C=2^{C} parts equally, c is a positive integer smaller than p, and the size of each part is B/C, represented by B, respectively, where i=1, 2, . . . , C. The PPSRC for each block file B with the operand of the code being F₂_{^{B/C}} is structured, and it can be represented using the B/C-dimensional vectors of the finite field F₂.

In step S43, the coset of the subgroup is used to divide the projective space, and B/C subspaces are selected to correspond to the storage nodes. In this step, the subgroup coset of the space constituted by B/C-dimensional vectors of the second finite field F₂, namely F₂_{^{B/C}} is used to divide the space into

$$\frac{{2}^{B / C} - 1}{{2}^{t + 1} - 1}$$

subspaces. B/C subspaces is chosen from the

$$\frac{{2}^{B / C} - 1}{{2}^{t + 1} - 1}$$

subspaces, with each selected subspace corresponding to one storage node, thus B/C storage nodes can be obtained. If the space constituted by (B/C) dimensional vectors is the space P, the projective subspace set is S, formed by the t dimensional subspace of space P, wherein (t+1)|B/C and (2^{t+1}−1)|(2^{B/C}−1). Each subspace of the space P is the (t+1) dimensional vector space F₂_{^{t+1}} of the finite field F₂, so it can be represented by (t+1) vectors of the finite field F₂. Suppose t+1=α₁, αt=Cα₁, each node stores (t+1) vectors of the finite field F₂, the data size stored in each node is α=Cα₁, and the maximum number of the storage nodes is

$$n = \frac{{2}^{B / C} - 1}{{2}^{t + 1} - 1} .$$

### Because

$$\frac{{2}^{B / C} - 1}{{2}^{t + 1} - 1}$$

storage nodes have some unnecessary redundant nodes, B/C nodes are selected from

$$\frac{{2}^{B / C} - 1}{{2}^{t + 1} - 1}$$

as the storage node of PPSRC.

In this embodiment, more specifically, this step can be further divided into the steps of: obtaining the multiplicative group F*₂_{^{B/C}} of the second finite field F₂; suppose w is the generating element of the multiplicative group F*₂_{^{B/C}} of the second finite field, obtaining the multiplicative group F*₂_{^{t+1}} of the first finite field F₁; suppose v is the generating element of the multiplicative group F*₂_{^{t+1}} of the first finite field, for any w^{a}εF*₂_{^{B/C}}, w^{a}F*₂_{^{t+1}}={w^{a}·v^{j}|v^{j}εF*₂_{^{t+1}}}, wherein, w^{a} is the representative element of the coset, a=0,

$$1 , … , \frac{{2}^{B / C} - 1}{{2}^{t + 1} - 1} - 1 ;$$

using the coset w^{a}F*₂_{^{t+1}} to divide the space of the second finite field F₂_{^{B/C}} to obtain

$$\frac{{2}^{B / C} - 1}{{2}^{t + 1} - 1}$$

subspace and choosing B/C subspaces from the subspaces and make each subspace selected correspond to one storage node.

Suppose the generator polynomial of the finite field F₂_{^{B/C}} is

$$f ( x ) = {x}^{B / C} + {C}_{\frac{B}{{C}^{- 1}}} {x}^{\frac{B}{{C}^{- 1}}} + … + {C}_{1} x + {C}_{0}$$

The multiplicative group of the finite field F₂_{^{B/C}} is represented as F*₂_{^{B/C}}. Its generating element is w, then w²^{^{B/C}}⁻¹=1, F*₂_{^{t+1}} is a subgroup of the cyclic group F*₂_{^{B/C}}. The generating element of the subgroup F*₂_{^{t+1}} is V, then v²^{^{t+1}}⁻¹=1. For any w^{a}εF*₂_{^{B/C}}, the set w^{a}F*₂_{^{t+1}}={wa·vj|vjεF*₂_{^{t+1}}} is the coset of the subgroup F*₂_{^{t+1}} and w^{a} is the representative element of the coset. In the paper, <v> is used to represent the subset F*₂_{^{t+1}}, and w^{a}<v> is used to represent the coset of w^{a} in the subgroup <v>.

The number of different cosets of subgroup H in group G is called the index of H in G, expressed as [G:H].

According to the Lagrange's theorem, suppose H is the subgroup of finite group G, then |G|=|H|·[G:H], and the index [G:H] is the number of coset of H in G.

The number of element of subgroup F*₂_{^{t+1}} is 2^{t+1}−1, so according to Lagrange's theorem, the number of cosets of subgroup F*₂_{^{t+1}} in group F*₂_{^{B/C}} is

$$\frac{{2}^{B / C} - 1}{{2}^{t + 1} - 1} ,$$

Therefore, when choosing the projective subspace of space P during the structuring of the code word, one condition is (2^{B/C}−1)|(2^{t+1}−1). In

$$\frac{{2}^{B / C} - 1}{{2}^{t + 1} - 1} ,$$

the representative element of each coset is w^{a}, a=0,

$$1 , … , \frac{{2}^{B / C} - 1}{{2}^{t + 1} - 1} - 1.$$

An encoding matrix can be obtained in step S44. One row of element of the encoding matrix is the encoding vectors of one storage node. In this step, if t+1 mutually independent vectors of the base finite field are used to represent each subspace, then each storage node can store t+1 vectors of the base finite field. The data storage volume is α=Cα₁, wherein α₁=t+1, C is the number of equal division. The t+1 vectors of one subspace are one row vector of the encoding matrix. Vectors in the B/C subspaces arrange to make the encoding matrix. The data set obtained from one row of vector of the encoding matrix multiplied by the equally divided data blocks respectively is the data set stored in one storage node.

In this embodiment, this step can be further divided into obtaining matrix gate T from the t+1 dimensional projective subspace. The matrix gate T is M×α₁ matrix gate, wherein, M is the matrix row,

$$M = \frac{{2}^{B / C} - 1}{{2}^{t + 1} - 1} ,$$

α₁ is the queue of the matrix gate T, the elements in each row are the t+1 mutually independent elements in each coset w^{a}F*₂_{^{t+1}}, and choosing the first B/C rows of the matrix gate T to obtain the encoding matrix T′. Elements in one row of the encoding matrix T′ are the encoding vectors of one storage node.

Generally speaking, during the structuring of PPSRC in this embodiment, there are

$$\frac{{2}^{B / C} - 1}{{2}^{t + 1} - 1}$$

cosets in all, and each coset has (2^{(t+1)}−1) elements, wherein there are (t+1) mutually independent elements. (t+1) mutually independent elements in each coset w^{a}<v> are being chosen as the encoding vectors of (d+1) storage nodes, where a=0,

$$1 , … , \frac{{2}^{B / C} - 1}{{2}^{t + 1} - 1} - 1$$

All (t+1) dimensional projective subspaces constitute the encoding matrix T(M×α₁), wherein

$$M = \frac{{2}^{B / C} - 1}{{2}^{t + 1} - 1} .$$

For any 1≦/≦α₁ and positive integer k which is not bigger than M, the k row l queue of the encoding matrix T can be obtained through XOR from several elements of the first B/C elements of the l queue vector of T, namely,

$${V}_{( k - 1 ) {α}_{1} + 1} = {μ}_{( \frac{B}{{C}^{- 1}} )} {v}_{{( \frac{B}{{C}^{- 1}} )}^{{α}_{1} + 1}} + {μ}_{( \frac{B}{{C}^{- 2}} )} {v}_{{( \frac{B}{{C}^{- 2}} )}^{{α}_{1} + 1}} + … + {μ}_{1} {v}_{{α}_{1} + 1} + {μ}_{0} {v}_{1}$$

$${μ}_{j} = \{ 0 , 1 \} , j = 0 , 1 , … , ( \frac{B}{C} - 1 )$$

$$T = [ \begin{matrix}{V}_{1} & {V}_{2} & … & {V}_{{α}_{1}} \\ {V}_{{α}_{1} + 1} & … & & {V}_{2 {α}_{1}} \\ … & … & & … \\ {V}_{k {α}_{1} + 1} & … & & {V}_{2 k {α}_{1}} \\ … & … & & … \\ {V}_{M {α}_{1} + 1} & … & & {V}_{2 M {α}_{1}}\end{matrix} ]$$

For any w^{j}, j is an arbitrary integer number. The generator polynomial of the finite field is

$$f ( x ) = {x}^{B / C} + {C}_{\frac{B}{{C}^{- 1}}} {x}^{\frac{B}{{C}^{- 1}}} + … + {C}_{1} x + {C}_{0}$$

so we have

$${w}^{a} = {μ}_{( \frac{B}{{C}^{- 1}} )} {W}^{( \frac{B}{{c}^{- 1}} )} + {μ}_{( \frac{B}{{C}^{- 2}} )} {W}^{( \frac{B}{{c}^{- 2}} )} + … + {μ}_{1} w + {μ}_{0}$$

$${μ}_{j} = \{ 0 , 1 \} , j = 0 , 1 , … , ( \frac{B}{C} - 1 )$$

In other words, representative elements w^{a}, a=0,

$$1 , … , \frac{{2}^{B / C} - 1}{{2}^{t + 1} - 1} - 1$$

of each coset can be expressed as the addition of several elements in representative elements

$${w}^{i} , i = 0 , 1 , 2 … , ( \frac{B}{C} - 1 )$$

of the coset. Therefore, all elements of the coset w^{a}<v> can be expressed as the addition of several elements of coset w^{j}<v>, j=1, 2, . . . , (B/C−1).

When structuring PPSRC, the front B/C rows of matrix gate T are chosen as the encoding matrix of the storage node. The encoding matrix T′ is:

$${T}^{′} = [ \begin{matrix}{V}_{1} & {V}_{2} & … & {V}_{{α}_{1}} \\ {V}_{{α}_{1} + 1} & … & & {V}_{2 {α}_{1}} \\ … & … & & … \\ {V}_{k {α}_{1} + 1} & … & & {V}_{2 k {α}_{1}} \\ … & … & & … \\ {V}_{{M}^{′} {α}_{1} + 1} & … & & {V}_{2 {M}^{′} {α}_{1}}\end{matrix} ]$$

$$wherein {M}^{′} = \frac{B}{C}$$

Elements of any queue of the encoding matrix T′ are mutually independent.

The first queue elements of the encoding matrix T′ are the representative elements of B/C cosets. Apparently, representative elements of these cosets are mutually independent. The l queue elements of the encoding matrix are obtained from the first queue element multiplied by W^{LM}, 1≦l≦α₁,

$$M = \frac{{2}^{B / C} - 1}{{2}^{t + 1} - 1} .$$

Therefore, the l queue elements of the encoding matrix are also mutually independent.

In step S45, the encoding data stored in each storage node are obtained and stored in the storage node. In this step, the encoding data stored in each storage node is obtained according to the encoding vectors of each storage node and store the encoding data in the storage node. In this embodiment, V={V₁, V₂, . . . V_{B/C}} is made as the vector set of nα₁ stored in n storage nodes, wherein

V₁={V_{α}_{₁}}

is the vector stored in the first node,

V₂={Vₐ_{₁}₊₁,V₂ₐ_{₁}}

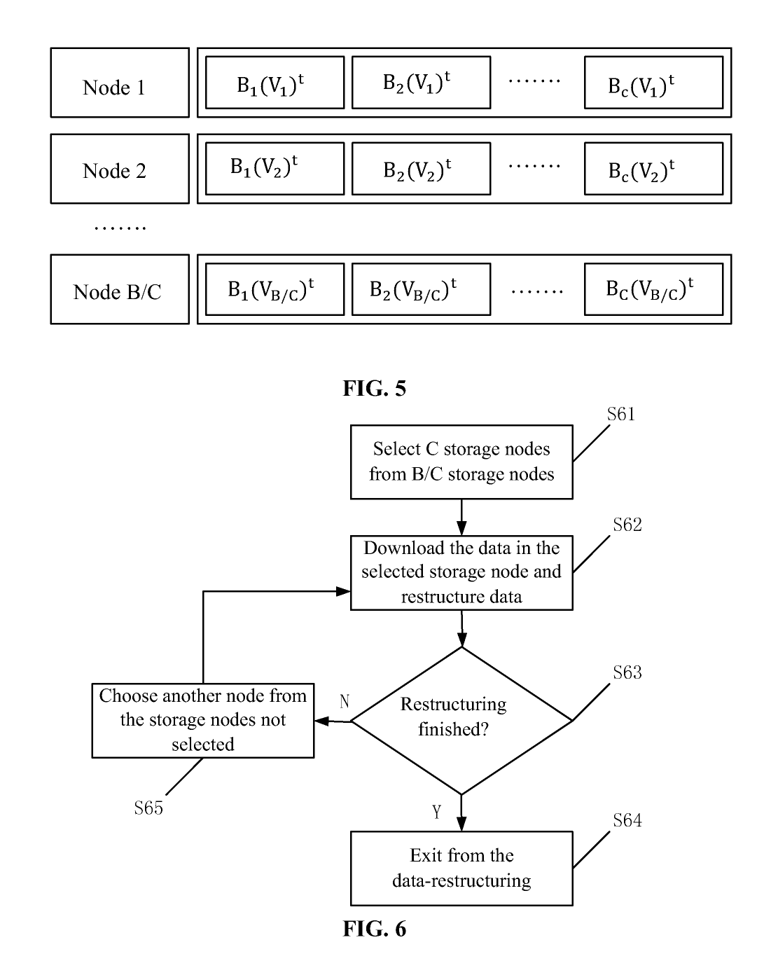

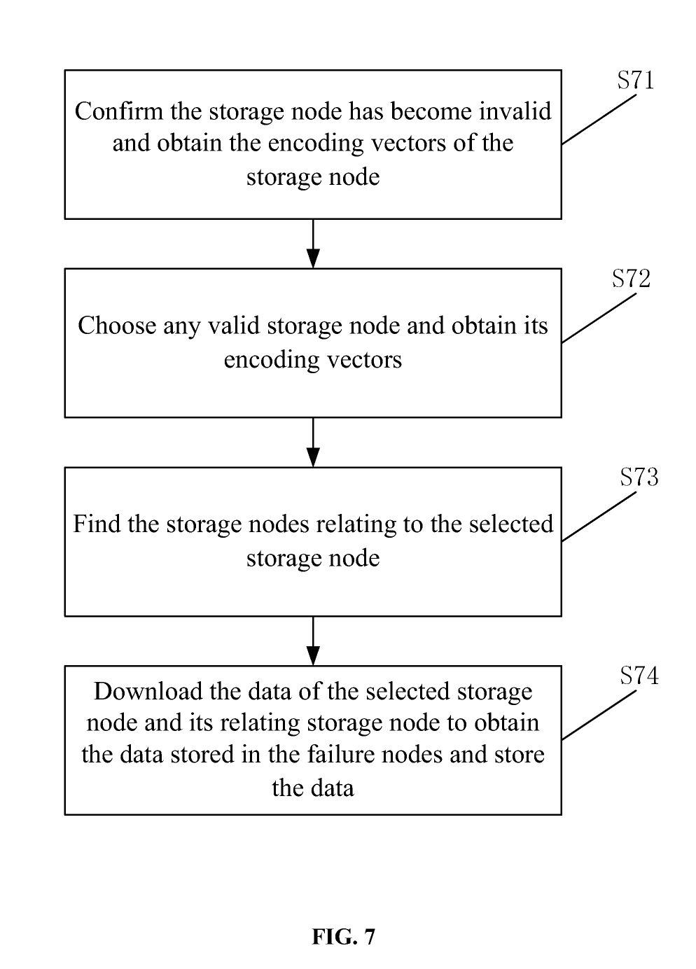

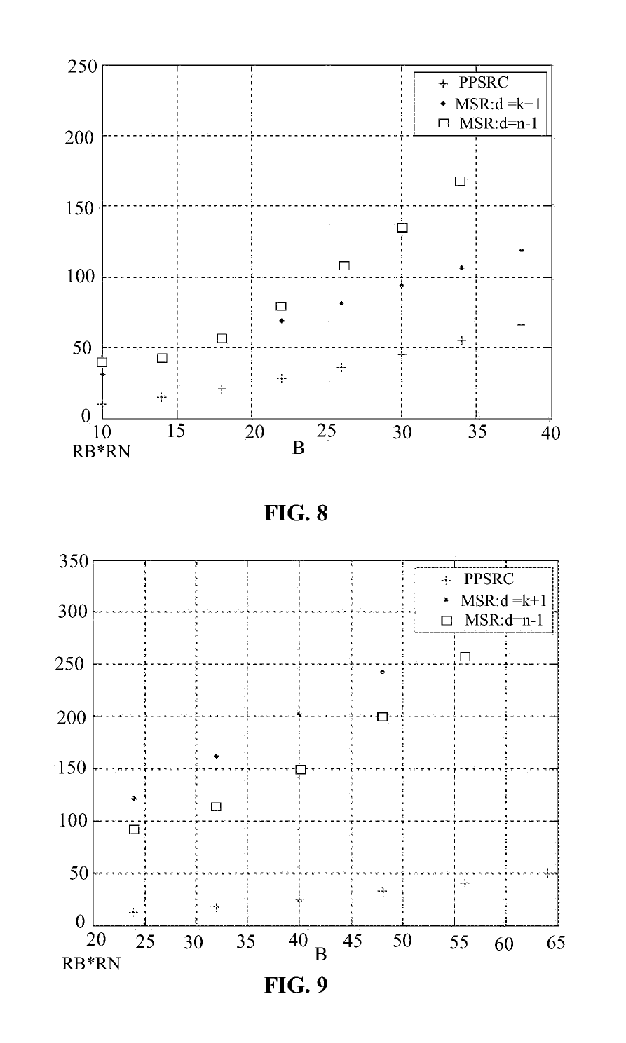

is the vector stored in the second node, and thus the vectors stored in other nodes can be obtained. The data size α=Cα₁ stored in the k node is {BᵢV_{(k-1)α}_{₁}₊₁^{T}, . . . , BᵢV_{kα}_{₁}^{T}}, wherein B, is the data block after equal division, i=1, 2, . . . , C, v^{T} is the row vector of the encoding matrix corresponding to the storage node. The value range of k is k=1, 2, . . . , B/C. FIG. 5 shows the structure of encoding data stored in each storage node of the embodiment. In FIG. 5, there are B/C storage nodes, with the data size stored in each node being C(t+1). The data in queue i are called Bᵢ structure code, because the code word stored in queue i is the encoding of data Bᵢ.

The embodiment also relates to a method for restructuring data in the distributed network storage system which adopts the encoding method, which includes the steps S61, S62, S63, S64 and S65.

Step S61: In this step, C storage nodes are selected randomly from B/C storage nodes which store the encoding data of storage file. Here, C is the number of equal division of the original data in encoding, and B is the size of the original file. When downloading the queue 1 encoding data of Bᵢ structure code, i=1, C, 1≦1≦α₁, there are (t+1)^{c} choices. Any queue of elements of the encoding matrix are mutually independent, and in each queue, there are M′=B/C elements, so M′ original data can be decoded, and the original data can be restored through downloading the structure code word Bᵢ, i=1, . . . , C of queue C.

Step S62: In this step, the data of the selected storage nodes i being downloaded respectively and the storage file is restructured according to the encoding vectors of these storage nodes. In the embodiment, the encoding vectors of the selected storage nodes are obtained respectively from the server. In some circumstances, the encoding vectors can also be obtained from the selected storage nodes.

Step S63: In this step, whether the restructuring file has been finished is being judged, that's to say, whether the file has been restructured. If so, step S64 is executed otherwise, the method skips to step S65.

Step S64: In this step, the method exits from the data restructuring. The stored file has been obtained in this step.

Step S65: In this step, another node is selected from the storage nodes which are not selected The file data have not been restructured using the data downloaded from the selected storage nodes, so one storage node is selected from those not selected, so that there is one more storage node selected, and then skip to step S62.

The embodiment also relates to a method for repairing invalid storage nodes in the distributed network storage system which adopts the encoding method, which includes the steps S71, S72, S73 and S74.

Step S71: The storage node has become invalid and the encoding vectors of the storage node are obtained. In this step, in order to confirm a storage node has become invalid, the data stored in the storage node need to be repaired and stored to another storage node; In the meantime, the encoding vectors of the storage node are obtained from the server.

Step S72: Any valid storage node is chosen and its encoding vectors are obtained. Any one node from the invalid storage nodes is chosen and at the same time, the encoding vectors of the storage node are obtained from the server.

Step S73: The storage nodes relating to the selected storage node are being searched: In this step, the encoding vectors of at least one storage node relating to the selected storage node is obtained through the calculation of the encoding vectors of the invalid storage nodes and selected storage node, and then the storage nodes corresponding to these encoding vectors are searched on the server; In this step, XOR operation is adopted. In the embodiment, “relating to the selected storage node” means addition of the encoding vectors of the selected storage node and the other storage node relating to it equals to the encoding vectors of the invalid storage nodes.

Step S74: The data of the selected storage node and its relating storage node is downloaded to obtain the data stored in the failure nodes and the data is stored. In this step, the data stored in the selected storage node and its relevant storage node is downloaded and restructured according to their corresponding encoding vectors (including the encoding vectors of the invalid storage nodes, selected storage node and the related storage node), to obtain the data stored in the failure nodes and the data is stored in a new storage node.

In the PSRC (n, k) of this embodiment, when the data size lost from one storage node is a, one datum can be downloaded from (a+1) storage nodes at most, and the repaired bandwidth is a+1.

Its observed from the repairing process of PSRC that one invalid datum can be restored through choosing the datum of one node and downloading one datum of the other node accordingly. Suppose the encoding vector of the data lost from one node is vᵢ, v₂, . . . , vₐ, the encoding vector u₁ of one node and the encoding vector u₂ of the other corresponding node can be selected arbitrarily, and make v₁=u₁+u₂. Then, choose one encoding vector for repairing v₂ is u₂ and its corresponding encoding vector u₃, and make v₂=u₂+u₃. Similarly, v₃=u₃+u₄, . . . vₐ=uₐ+uₐ₊₁. Therefore, for repairing encoding vector v₁, v₂, . . . , vₐ, encoding vectors (u₁, U₂, . . . , Uₐ₊₁) from at most (a+1) storage nodes are downloaded, and the repaired bandwidth is a+1. v₁, v₂, . . . , vₐ(uᵢ, u₂, . . . , uₐ₊₁)

The node of PPSRC (n, k) is B/C, and it does not fit for the above repairing process. However, generally speaking, for the lost data v₁, v₂, . . . , vₐ of PPSRC (n, k), the repaired bandwidth is at least (a+1).

For PPSRC, suppose the encoding vector of one node vᵢ is lost. Any one row from B/C−1 rows of vectors is chosen, from B/C−1 choices. There are x=(B/C−1)2^{t+1}) encoding vectors obtained from the internal arithmetic of each row of vectors. The deleted matrix gate (T−T′) has (t+1)

$$( \frac{{2}^{B / C} - 1}{{2}^{t + 1} - 1} - \frac{B}{C} )$$

elements, and the matrix gate T has (t+1)

$$( \frac{{2}^{B / C} - 1}{{2}^{t + 1} - 1} )$$

elements, so the probability for the result of the XOR operation of one element in matrix gate T′ with the lost vector v₁ to belong to the deleted matrix gate (T−T′)

$${p}_{1} = \frac{( t + 1 ) ( \frac{{2}^{B / C} - 1}{{2}^{t + 1} - 1} - \frac{B}{C} )}{( t + 1 ) ( \frac{{2}^{B / C} - 1}{{2}^{t + 1} - 1} )} = \frac{( \frac{{2}^{B / C} - 1}{{2}^{t + 1} - 1} - \frac{B}{C} )}{( \frac{{2}^{B / C} - 1}{{2}^{t + 1} - 1} )}$$

Therefore, the probability that the lost vector vᵢ cannot be repaired by two vectors is p=p₁^{x}, x=(B/C−1) 2^{t+1}) apparently, p₁ is smaller than 1, but in the general situation, x is very big, so the probability of p is very small. The number of lost vectors v₁ that can be repaired is

$${n}_{repair} = \frac{( \frac{B}{C} )}{( \frac{{2}^{B / C} - 1}{{2}^{t + 1} - 1} )}$$

$$x = \frac{( \frac{B}{C} )}{( \frac{{2}^{B / C} - 1}{{2}^{t + 1} - 1} )} ( \frac{B}{C} - 1 ) {2}^{( t + 1 )}$$

For example, if B=16, C=2, (t+1)=4, then

$$p = ( \frac{8}{17} ) 112 \approx 1.16 \times {10}^{- 31}$$

$${n}_{repair} = \frac{112 \times 8}{17} \approx 52.7$$

Therefore, for a lost vector v₁, the repaired bandwidth of PPSRC is generally 2.

In PPSRC, each storage node stores C(t+1) data size. According to the above analysis, the repaired bandwidth of PPSRC is at least C(t+2). If B=ka=kC (k+1), then

$$( t + 1 ) = \frac{B}{kC} ,$$

so me repaired bandwidth of PPSRC can be expressed as

$$C ( \frac{B}{C - k} + 1 ) ;$$

the repaired bandwidth of MSR is

$$\frac{Bd}{k ( d - k + 1 )} , d > k . If C ( \frac{B}{C - k} + 1 ) < \frac{Bd}{k ( d - k + 1 )} ,$$

then

$$B > \frac{C}{( \frac{d}{k ( d - k + 1 )} - \frac{1}{k} )} .$$

Therefore, when B is big enough, the repaired bandwidth of PPSRC is superior to that of MSR. Actually, when B=32, C=2, t+1=2, n=16, α=(t+1) C=4. For PPSRC (16, 8), d=3, the repaired bandwidth is 6. For MSR (16, 8), when d takes the maximum value 15, its minimum repaired bandwidth is

$$\frac{32.15}{8 ( 15 - 8 + 1 )} = 7.5 .$$

When d=9, the repaired bandwidth is

$$\frac{32.9}{8 ( 9 - 8 + 1 )} = 18.$$

Therefore, the repaired bandwidth of PPSRC is superior to that of MSR. Because the repaired bandwidth and repaired node of MSR are interactional, the general performance of repaired bandwidth and repaired node of MSR and PPSRC can be evaluated through the repaired bandwidth multiplied by the repaired node. In FIG. 8, the performance of PPSRC in the premise of C=2, k=4 is evaluated. In FIG. 9, the performance of PPSRC in the premise of C=2, k=8 is evaluated.

In the embodiment, one practical condition is to make c=0, c=2^{c}=1, B/C=8. Suppose the generator polynomial of the finite field F₂_{⁸} is f(x)=x⁸+x⁴+x³+x²+1, and the generating element of its multiplicative group F*₂_{⁸} is w, then, the result is w²^{⁸}⁻¹=w²⁵⁵=1. Because (2⁴−1)|(2⁸−1), the subgroup of the multiplicative group F*₂_{⁸} is F*₂_{⁴}, namely, (t+1)=4, the generating element of subgroup F*₂_{⁴} is v, v²^{⁴}⁻¹=v¹⁵=1, and v=w¹⁷. The multiplicative group F*₂_{⁸} has

$$\frac{{2}^{B / C} - 1}{{2}^{t + 1} - 1} = 17$$

cosets in all. According to the determination of storage nodes during the structuring of PPSRC, vectors of the first 8 cosets are taken as the encoding vectors of storage nodes. The coset 1.<v>={1, w¹⁷, w³⁴, . . . , w²³⁸} is a subspace of P space, and the dimension of the subspace is 4. The coset 1.<v> has 2^{t+1}−1=15 elements, so 15 −4=11 elements need to be deleted, and only 4 elements are left. Because the generator polynomial of the finite field F*₂_{⁸} is f(x)=x⁸+x⁴+x³+x²+1, make 1=00000001, w=00000010, w²=00000100, w³=00001000, w⁴=00010000, w⁵=00100000, w⁶=01000000, w′=10000000, and other elements in the multiplicative group F*₂_{⁸} can be calculated out from the generator polynomial. 1+w¹⁷=w⁶⁸ can be worked out. Any two from {1, w¹⁷, w⁶⁸} are chosen; suppose {1, w¹⁷} are chosen. Similarly, 1+w³⁴=w¹³⁶, 1+w⁵¹=w²³⁸, 1+w⁸⁵=w¹⁷⁰, 1+w¹⁰²=w²²¹, 1+w¹¹⁹=W¹⁵³, 1+w¹⁸⁷=w²⁰⁴, w¹⁷+w³⁴=w⁸⁵, w¹⁷+w⁵¹=w¹⁵³, w¹⁷+w¹⁰²=IV w¹⁸⁷, w¹⁷+w¹¹⁹=w²³⁸, w³⁴+w⁵¹=W¹⁰², 1+w¹⁷+w⁵¹=W¹¹⁹.

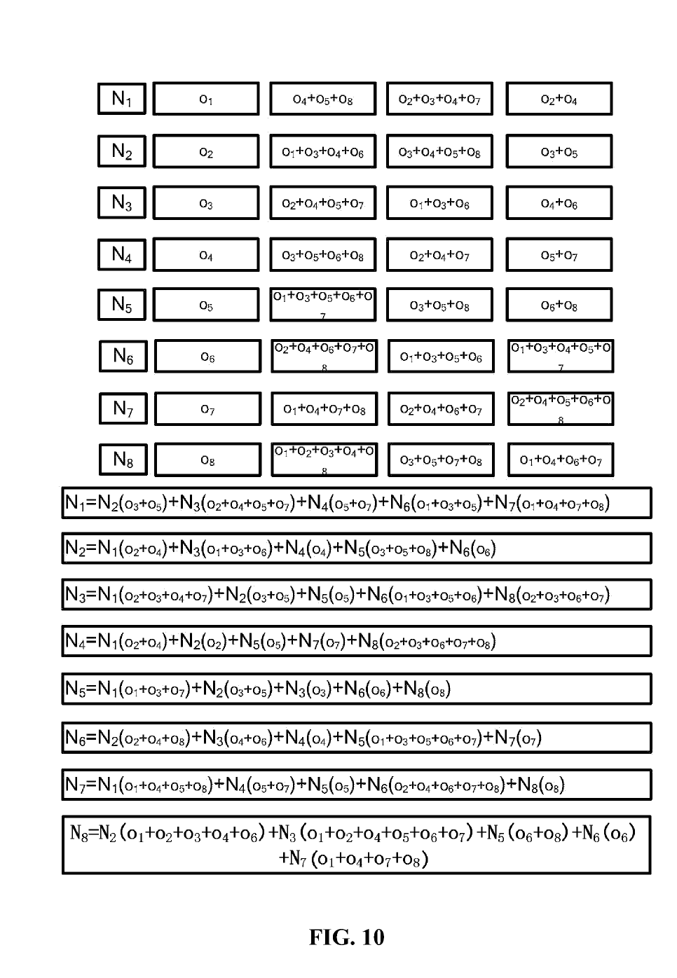

In coset 1.<v>, the elements on the right of all the above equations are deleted, and the set after the elements are deleted from coset 1.<v> is the vector space in which the storage node 1 is stored, namely N₁={1, w¹⁷, w³⁴, w⁵¹}. Similarly, the vector spaces stored in the other 7 storage nodes are respectively N₂={w, w¹⁸, w³⁵, w⁵²}, N₃={w², w¹⁹, w³⁶, w⁵³}, N₄={w³, w²⁰, w³⁷, w⁵⁴}, N₅={w⁴, w²¹, w³⁸, w⁵⁵}, N₆={w⁵, w²², w³⁹, w⁵⁶}, N₇={w⁶, w²³, w⁴⁰, w⁵⁷}, N₈={w⁷, w²⁴, w⁴¹, w⁵⁸}. The data B stored are O={O₁, O₂, O₃, O₄, O₅, O₆, O₇, O_{8}}. FIG. 10 shows the storage of PPSRC (8, 2). In FIG. 10, N₁=N₂(O₃+O₅)+N₃(O₂+O₄+O₅+O₇)+N₄(O₅+O₇)+N₆(O₁+O₃+O₅)+N₇(O₁+O₄+O₇+O₈) is expressed as the repairing process of node 1, the data stored in node 1 can be repaired through downloading (O₃+O₅) of node 2, (O₂+O₄+O₅+O₇) of node 3, (O₅+O₇) of node 4, (O₁+O₃+O₅) of node 6, and (O₁+O₄+O₇+O₈) of node 7. The equations in the process of repair of other nodes are similar.

Because k=2, the encoding data is chosen from any two nodes, and the original data can be decoded. Any two nodes can decode the original data, so when any one code becomes invalid, data of two nodes can be downloaded to recover the data of the failure node. This process can also be realized through connecting 5 storage nodes and downloading 1 datum from each storage node. For example, if 4 data of node 1 become invalid, firstly, {u₁=00010100} of node 2 and encoding vector {u₂=00100000+00110101=00010101} of node 6 are downloaded to repair vector {v₁=u₁+u₂=00000001}. According to the general repairing process of the minimum repaired bandwidth, {u₃=01011010} of node 3, {u₄=01010000} of node 4, and {u₅=11001001} of node 7 are downloaded to recover all failure data of node 1. The repairing process is {v₁=u₁+u₂, v₃=u₁+u₃, v₄=u₄+u₃, v₂=u₅+u₄+u₁}. The repaired bandwidth is 5, and the repaired node is 5. The repaired bandwidth of other nodes is also 5.

In the embodiment, another practical condition is to make C=1, C=2^{C}=2, then B/C=4, the base finite field is F₂ and its elements are 0 and 1. Because (2²−1)|(2⁴−1), take t=1. Considering 1-stretch, the first finite field obtained is F₄; suppose m=B/C=4, the second finite field is F₁₆.

Under such circumstances, the parameters of PPSRC are B=8, B/C=4, a=2, n=1+2²=5. Because coset w⁴F*₄ is completely the XOR of coset F*₄ and coset w F*₄, it can be deleted. There are 4 storage nodes in all, which can be represented by Nᵢ, i=1, . . . , 4 respectively. Because C=2, the data size stored in each storage node is Cα=4, and the original data needing to be stored can be represented by O₁=(O₁, O₂, O₃, O₄) and O₂=(O₅, O₆, O₇, O₈). The table below shows the data stored in each storage node.

TABLE 1
Storage System of PPSRC (4, 2)

| Node | Basic vector | Stored data |
|---|---|---|
| N₁ | v₁ = (1000), v₂ = (0110) | {O₁, O₂ + O₃ } {O_{5,} O₆ + O₇} |
| N₂ | v₃ = (0100), v₄ = (0011) | {O_{2,} O₃ + O₄} {O_{6,} O₇ + O₈} |
| N₃ | V₅ = (0010), v₆ = (1101) | {O_{3,} O₁ + O₂ + O₄} |
| | | {O_{7,} O₅ + O₆ + O₈} |
| N₄ | v₇ = (0001), v₈ = (1010) | {O_{4,} O₁ + O₃} {O_{8,} O₅ + O₇} |

In this way, the original data can be recovered from any two storage nodes, and when any two nodes become invalid, the data stored in the failure nodes can be recovered from the rest 2 storage nodes.

In the embodiment, the redundancy coefficient of PPSRC is

$$\begin{matrix}R = n α \text{/} B \\ = \frac{\frac{B}{C} C ( t + 1 )}{B} \\ = ( t + 1 ) \\ = {2}^{p - c - 1}\end{matrix}$$

When B is determined, P can also be determined, and the redundancy coefficient can be changed by changing c, so the redundancy coefficient of PPGRC is controllable. The maximum value of c can be P−1. Under such circumstances, MPGRC has no redundancy, and the data stored are original data. When c=p−2, the redundancy coefficient of PPSRC is 2; when c=0, the redundancy coefficient of MPGRC is the biggest, 2^{p-1}. The redundancy coefficient of PSRC is

$$\begin{matrix}R = n α \text{/} B \\ = \frac{( \frac{{2}^{B} - 1}{{2}^{t + 1} - 1} ) ( t + 1 )}{B} \\ = \frac{( {2}^{B} - 1 )}{( {2}^{t + 1} - 1 )} \frac{( t + 1 )}{B}\end{matrix}$$

Because B> (t+1), 2B is further bigger than 2¹⁺¹. Therefore, when B takes a big value, the redundancy coefficient of PSRC is also very big. Table 2.1 is the comparison of redundancy of PPSRC and PSRC when B=16. Table 2.2 is the comparison of redundancy of PPSRC and PSRC when B=32 and it can be observed from table 2.1 and table 2.2, when B=16, the minimum redundancy of PSRC is 128.5 when B=32, the minimum redundancy of PSRC is 32768.5. Therefore, the redundancy of PSRC is very big, while the redundancy of PPSRC is controllable.

TABLE 2.1
Redundancy coefficient of OPSRC (n, 2) and PSRC when B = 16

| | OPSRC: c | | |
|---|---|---|---|
| | 1 | 2 | 3 |
| Redundancy of | 4 | 2 | 1 |
| OPSRC | | | |
| Storage nodes of | 8 | 4 | 2 |
| OPSRC n | | | |
| PSRC: t + 1 | 2 | 4 | 8 |
| Redundancy of | 2730.625 | 1092.25 | 128.5 |
| PSRC | | | |
| Storage nodes of | 21845 | 4369 | 257 |
| PSRC n | | | |

TABLE 2.2
Redundancy coefficient of OPSRC (n, 2) and PSRC when B = 32

| | OPSRC: c | | | |
|---|---|---|---|---|
| | 1 | 2 | 3 | 4 |
| Redundancy | 8 | 4 | 2 | 1 |
| of OPSRC | | | | |
| Storage | 16 | 8 | 4 | 2 |
| nodes of | | | | |
| OPSRC n | | | | |
| PSRC: t + 1 | 2 | 4 | 8 | 16 |
| Redundancy | 89478485.3125 | 35791394.125 | 4201752.25 | 32768.5 |
| of PSRC | | | | |
| Storage | 1431655765 | 286331153 | 16843009 | 65537 |
| nodes of | | | | |
| PSRC n | | | | |

For the complexity of computation in this embodiment, the repaired node of RS is k, repaired bandwidth is B, the redundancy coefficient is controllable, and the amount of calculation of encoding is O(n²L). If Cauchy matrix is used for encoding, the amount of calculation of decoding can be the minimum, namely O(n²L). The repaired node of RGC is d (generally, d>k), its repaired bandwidth is generally smaller than B, and the redundancy is controllable. Both the encoding and decoding processes of RGC adopt the linear network encoding operation, while the encoding and decoding complexity of the linear network encoding is respectively O(M²L) and O(M²L+M³), wherein, M is the number of encoding pack, so the complexity of encoding and decoding of the regenerating codes is respectively O(n²α²L) and O(n²α²L+n³α³). The repaired node of PSRC is k=2, and the repaired bandwidth is 2α. The repaired node in the general repairing process in this paper is (a+1), and the repaired bandwidth is (a+1). The encoding and decoding processes of PSRC adopt XOR operation, while the complexity for m data packs to use XOR for encoding is O (ML). L is the length of data pack, the complexity to decode M encoding packs is O (MmL), so the complexity of encoding and decoding of PSRC is respectively

$$O ( n αL ) = O ( \frac{{2}^{B} - 1}{{2}^{( t + 1 )} - 1} ( t + 1 ) L ) and$$

$$O ( nk {α}^{2} L ) = O ( \frac{{2}^{B} - 1}{{2}^{( t + 1 )} - 1} {k ( t + 1 )}^{2} L )$$

(the restructuring process of PSRC is not given, so the minimum value is taken here).

The redundancy coefficient of PSRC is very big. The repaired node of PPSRC is (α+1), and the minimum repaired bandwidth is (α+1). The encoding and decoding complexity is respectively

$$O ( n αL ) = O ( B ( t + 1 ) L ) and$$

$$\begin{matrix}O ( nk {α}^{2} L ) = O ( \frac{B}{C} K \cdot {{C}^{2} ( t + 1 )}^{2} \cdot L ) \\ = O ( BC \cdot k \cdot {( t + 1 )}^{2} )\end{matrix}$$

The redundancy is controllable. Table 3 summarizes the performance of different code words.

TABLE 3
Performance Comparison of Different Code Words

| | | Repaired | Repaired | Restructured | Computation Complexity | | Redundancy |
|---|---|---|---|---|---|---|---|
| | | Node | Bandwidth | Bandwidth | Encoding | Decoding | Coefficient |
| RS | | k | B | B | O(n²L) | O(n²L) | Controllable |
| Regenerating | M | Bigger | Smaller | B | O(n²α²L) | O(n²α²L) + n³α³ | Controllable |
| Code | S | than k | than B | | | | |
| | R | | | | | | |
| | M | Bigger | α | Bigger | | | Controllable |
| | B | than k | | than B | | | |
| | R | | | | | | |

| | | | | | | |
|---|---|---|---|---|---|---|
| PSRC | d = 2 or (α + 1) | 2α or (α + 1) | Bigger than B | $O ( \frac{{2}^{B} - 1}{{2}^{( t + 1 )} - 1} ( t + 1 ) L )$ | $O ( \frac{{2}^{B} - 1}{{2}^{( t + 1 )} - 1} {k ( t + 1 )}^{2} L )$ | Uncontrollable |
| PPSRC | (α + 1) | At least | B | O(B(t + 1)L) | O(BC.k(t + 1)²) | Controllable |
| | | (α + 1) | | | | |

Besides, in the embodiment, the encoding and self-repairing of PPSRC only relate to XOR operation, not like HSRC, of which the encoding requires the calculation of polynomials and is relatively complicated. Besides, the complexity of computation of PPSRC is smaller than that of PSRC. Meanwhile, the repaired bandwidth and repaired node of PPSRC are superior to those of MSR. What is worth mentioning is that the redundancy of PPSRC is controllable and its applicable to common storage systems; the restructured bandwidth of PPSRC can be the optimal.

The above embodiments only express several forms of exploitation of the invention. They are described specifically and in detail, but they shall not be considered the restriction over the patent scope of the invention. It should be noted that for the common technologists in this field, more deformations and improvements can be made on the premise of not breaking away from the concept of the invention. All these are within the reach of protection of the invention. Therefore, the reach of protection of the patent of invention shall be subjected to the annexed claims.

What is claimed is:

1. A computer-implemented encoding method for projective self-repairing codes used in a distributed storage system, the method comprising the steps of:
A) dividing an original data with a size of B=2^{p} equally into C parts, with size of each part being B/C, wherein p is a positive integer, C=2^{c}, wherein c is a positive integer smaller than p, wherein each data is capable of being represented as Bᵢ, i=1, 2, . . . , C after the equal division;
B) setting a base finite field F₂ and a second finite field F₂_{^{B/C}} according to the size B of the original data and the number of equal division C, wherein space constituted by B/C dimensional vectors of the second finite field F₂_{^{B/C}} is a projective space P and a t dimensional subspace of space P forms a t-stretch set S, wherein t+1|B/C and (2^{t+1}−1)|(2^{B/C}−1) the first finite field F₂_{^{t+1}} can be obtained from the t-stretch, wherein, F₂⊂F₂_{^{t+1}}⊂F_{q}_{^{B/C}};
C) dividing the space constituted by the B/C-dimensional vectors in the second finite field F₂_{^{B/C}} into
$$\frac{{2}^{B / C} - 1}{{2}^{t + 1} - 1}$$
subspaces using its subgroup coset by choosing B/C subspaces from the subspaces, with each selected subspace corresponding to one storage node, thus B/C storage nodes can be obtained;
D) representing each subspace using mutually independent t+1 vectors in the base finite field, and each storage node can store t+1 vectors of the base finite field, data storage volume is α=Cα₁, wherein α₁ t+1, C is the number of equal division, the t+1 vectors of one subspace are one row vector of an encoding matrix, vectors in the B/C subspaces arranged to make the encoding matrix a data set obtained from one row of vector of the encoding matrix multiplied by the equally divided data blocks respectively is the data set stored in one storage node; and
E) obtaining encoding data stored in each storage node according to the encoding vectors of each of the storage node and store the encoding data in the storage nodes.

2. The method of claim 1, wherein: a multiplicative group of the second finite field F₂_{^{B/C}} in step C) is F*₂_{^{B/C}}, w is a generating element of the multiplicative group of the second finite field, F*_{q}_{^{t+1}} is a multiplicative group of the first finite field, and it is a subgroup of a cyclic group F*₂_{^{B/C}}, its generating element is V, wherein, a=0,
$$1 , … , \frac{{2}^{B / C} - 1}{{2}^{t + 1} - 1} - 1 ,$$
and the coset is the coset of subgroup F*₂_{^{t+1}}.

3. The method of claim 2, wherein step C further comprises:
C1) obtaining the multiplicative group F*₂_{^{B/C}} of the second finite field, obtaining the multiplicative group F*₂_{^{t+1}} of the first finite field for any w^{a}εF*₂_{^{B/C}}, wherein w^{a}F*₂_{^{t+1}}={w^{a}·v^{j}|v^{j}εF*₂_{^{t+}}} is the coset of subgroup F*₂_{^{t+1}} and w^{a} is a representative element of the coset a=0,
$$1 , … , \frac{{2}^{B / C} - 1}{{2}^{t + 1} - 1} - 1 ;$$
C2) using the coset w^{a}F*₂_{^{t+1}} to divide the space of the second finite field F₂_{^{B/C}} to obtain
$$\frac{{2}^{B / C} - 1}{{2}^{t + 1} - 1}$$
subspace; and
C3) choosing B/C subspaces from the subspaces and make each subspace selected correspond to one storage node.

4. The method of claim 3, wherein the step D further comprises:
D1) obtaining matrix gate T from the t+1 dimensional projective subspace, wherein the matrix gate T is M×α₁ matrix gate, wherein M is a matrix row,
$$M = \frac{{2}^{B / C} - 1}{{2}^{t + 1} - 1} ,$$
α₁ is a queue of the matrix gate T, the elements in each row are t+1 mutually independent elements in each coset w^{a}F*₂_{^{t+1}}; and
D2) choosing the first B/C rows of the matrix gate T to obtain an encoding matrix T′, wherein elements in one row of the encoding matrix T′ are the encoding vectors of one storage node.

5. The method of claim 4, further comprising integrating the data stored in k storage node one by one as {BᵢV_{(k-1)α}_{₁}₊₁^{T}, . . . , BᵢV_{kα}_{₁}^{T}} to obtain the encoding data stored respectively in different storage nodes, wherein B, is the data block after equal division, i=1, 2, . . . , C, ν^{T} is the row vector of the encoding matrix corresponding to the storage node, value range of k is k=1, 2, . . . , B/C.

6. The method of claim 1, further comprising:
choosing C storage nodes arbitrarily in B/C storage nodes, wherein, C is the number of equal division during encoding of the original data, and B is the size of the original file;
downloading the data from the node selected and restructuring the data according to its encoding vectors;
determining whether data reconstruction has been finished, and exiting if finished from the data reconstruction, otherwise, carrying out the next step; and
choosing any one storage node from unselected storage nodes, thus there will be one more selected storage node, and then return to the step of downloading the data from the node selected.

7. The method of claim 6, wherein the step of downloading the data from the node selected and restructuring the data according to its encoding vectors, further comprises obtaining the encoding vectors of the storage nodes selected from a server respectively, or obtaining the encoding vectors of the selected storage nodes from them.

8. The method of claim 1, further comprising:
M) confirming a storage node has become invalid and obtaining the encoding vectors of the storage node from a server;
N) choosing any valid storage node and obtaining its encoding vectors;
O) obtaining the other storage node relating to the selected storage node, and obtaining the encoding vectors of the invalid storage node through the encoding vectors of the selected storage node and the other storage node; and
P) downloading the data of the selected storage node and its relating storage node, and obtaining the data of the invalid storage node according to these data and store the data in a new storage node to finish the data recovery.

9. The method of claim 8, wherein in the step O, the encoding vectors of the selected storage node plus the encoding vectors of the other storage node equals to the encoding vectors of the invalid storage node.

10. The method of claim 9, wherein in the step P, the data stored in the selected storage node and the relevant storage node are reconstructed to obtain the data stored in the invalid storage node.
